(19) United States
(12) Patent Application Publication
(10) Pub. No.: US 2021/0054494 A1
(43) Pub. Date: Feb. 25, 2021

(54) MASK ASSEMBLY, MANUFACTURING DEVICE AND MANUFACTURING METHOD THEREOF

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Wenbiao DING, Beijing (CN); Jia Zeng, Beijing (CN); Shuai Du, Beijing (CN); Kui Chen, Beijing (CN); Yong Zheng, Beijing (CN)

(21) Appl. No.: 16/812,796

(22) Filed: Mar. 9, 2020

(30) Foreign Application Priority Data
Aug. 19, 2019 (CN) 201910765171.6

(51) Int. Cl. C23C 14/04; C23C 14/24; H01L 51/00

(52) U.S. Cl. CPC C23C 14/042; H01L 51/0011; C23C 14/24

(57) ABSTRACT

The present disclosure discloses a manufacturing device of mask assembly including at least one mask, comprising a first stretching mechanism configured to clamp the edges of the mask in a first direction and stretch the mask in a second direction and a second stretching mechanism configured to clamp the edges of the mask in the second direction and stretch the mask in the first direction, wherein the first direction being perpendicular to the second direction. The disclosure also relates to a method of manufacturing a mask assembly and a mask assembly.

### CROSS-REFERENCE TO RELATED APPLICATION

This application claims the benefit of priority of Chinese Patent Application No. 201910765171.6, filed on Aug. 19, 2019, the disclosures of which are incorporated herein by reference in its entirety as part of the present application.

### TECHNICAL FIELD

Embodiments of the present disclosure generally relate to the field of display technology, and in particular, to a mask assembly, a manufacturing device and a manufacturing method thereof.

### BACKGROUND ART

The vapor deposition or evaporation process is one of the important processes for manufacturing the organic light emitting layer of the organic light emitting diode (OLED) display screen. In this process, it is necessary to use a mask assembly with a pattern to form the required pattern on the substrate to be vapor-deposited by vacuum evaporation. The mask assembly comprises a mask frame and a mask. The mask is tensioned and fixed to the mask frame in the stretching step of the process. However, when the mask is tensioned in the stretching step, the mask is often stretched unevenly in different directions, which will cause wrinkles in the mask and seriously affect the quality of the evaporation process.

### SUMMARY OF THE INVENTION

In view of this, the purpose of the present disclosure is to provide a mask assembly, a manufacturing device and a manufacturing method thereof, which can effectively avoid the wrinkle phenomenon of the mask and improve the quality of the evaporation process.

The embodiments of the present disclosure provide a manufacturing device of mask assembly including at least one mask, comprising: a first stretching mechanism configured to clamp the edges of the mask in a first direction and stretch the mask in a second direction; and a second stretching mechanism configured to clamp the edges of the mask in the second direction and stretch the mask in the first direction; wherein the first direction being perpendicular to the second direction.

Optionally, at least one of the first stretching mechanism and the second stretching mechanism may comprise:
a clamping unit configured to clamp the edges of the mask in the first direction or in the second direction;
a sliding unit configured to drive the clamping unit to move in the second direction or in the first direction, thereby causing the clamping unit to stretch the mask in the second direction or in the first direction.

In an embodiment of the present disclosure, the clamping unit may comprise a movable clamping jaw, a clamping jaw lifting part and a clamping jaw base; the movable clamping jaw can move along a third direction relative to the clamping jaw base under the driving of the clamping jaw lifting part, and the third direction is perpendicular to both the first direction and the second direction; a space is formed between the movable clamping jaw and the clamping jaw base to receive and clamp the edges of the mask in the first direction or in the second direction.

In an embodiment, the sliding unit may comprise a first sliding rail, a base and a second sliding rail; the first sliding rail extends along the first direction, the second sliding rail extends along the second direction, or vice versa. In other words, the extending direction of the first sliding rail is perpendicular to that of the second sliding rail. The first sliding rail may be fixed to the base, and the clamping unit may be arranged on the first sliding rail; the base may be arranged on the second sliding rail and can slide along the second sliding rail.

In an embodiment, the friction coefficient between the first sliding rail and the clamping unit may be different from that between the second sliding rail and the base.

In an embodiment, the manufacturing device may comprise a plurality of said first stretching mechanisms which arranged at equal intervals along the first direction; and a plurality of said second stretching mechanisms which are arranged at equal intervals along the second direction.

The present disclosure further provides a method of manufacturing a mask assembly, comprising the steps of:

providing the mask assembly including at least one mask;

clamping the edges of a mask of a mask assembly in a first direction by a first stretching mechanism of a manufacturing device of mask assembly, and stretching the mask along a second direction;

clamping the edges of the mask of the mask assembly in the second direction by a second stretching mechanism of the manufacturing device of mask assembly, and stretching the mask along the first direction;

wherein the first direction is perpendicular to the second direction.

In an embodiment, the method may further comprise:

using a plurality of first shielding strips and a plurality of supporting strips to form a grid holder on the mask frame;

sandwiching the mask between two adjacent first shielding strips;

wherein the plurality of first shielding strips may arranged in parallel in the first direction, the plurality of supporting strips may be arranged in parallel in the second direction, or vice versa, wherein the extending direction of the first shielding strips is perpendicular to that of the supporting strips.

In an embodiment, the method may further comprise:

fixing the edges of the mask parallel to and adjacent to the first shielding strips with the first shielding strips, after the mask being stretched and tensioned along the first direction and the second direction.

In an embodiment, the method may further comprise:

cutting the edges of the mask fixed with the first shielding strips to expose at least a portion of the first shielding strip;

arranging a second shielding strip at a gap between adjacent masks;

fixing the second shielding strip with the exposed portion of the corresponding first shielding strip.

In an embodiment of the present disclosure, the method may further comprise:

carrying out a pre-deformation treatment on a light-transmitting region of the mask.

The present disclosure also provides a mask assembly manufactured by the above manufacturing method.

In an embodiment, the mask assembly may comprise a mask frame, a plurality of first shielding strips, a plurality of supporting strips and at least one mask; the plurality of first shielding strips and the plurality of supporting strips may form a grid holder, wherein the grid holder is disposed on the mask frame; the mask may be sandwiched between two adjacent first shielding strips; the plurality of first shielding strips are arranged in parallel along a first direction, the plurality of supporting strips are arranged in parallel along the second direction, or vice versa, wherein the extending direction of the first shielding strips is perpendicular to the extending direction of the supporting strips.

In an embodiment, the edges of the mask parallel to and adjacent to the first shielding strips are fixed with the first shielding strips, after the mask being stretched and tensioned in the first direction and the second direction.

In an embodiment, the mask assembly may further comprise a second shielding strip; the edges of the mask fixed with the first shielding strips are cut to expose at least a portion of the first shielding strips, the second shielding strip is disposed at a gap between adjacent masks, and fixed with the exposed portion of the corresponding first shielding strip.

In an embodiment, the mask of the mask assembly has a pre-deformed light-transmitting region.

As can be seen from the above, the mask assembly, the manufacturing device and the manufacturing method provided by the embodiments of the present disclosure can, by stretching the mask in two directions, effectively reduce mask wrinkles, make the magnetic force bond between the magnetic plate of the evaporation device and the mask more tightly, reduce the gap between the substrate to be vapor-deposited and the mask, and reduce shadowing effect, improper color mixing and etc.

### BRIEF DESCRIPTION OF THE DRAWINGS

In order to explain the embodiments of the present disclosure or the technical solutions in the prior art more clearly, the drawings needed in the description of the embodiments or the prior art will be outlined. Obviously, the drawings in the following description only relate to some embodiments of the present disclosure. For those of ordinary skill in the art, other drawings can be obtained according to these drawings without creative efforts.

FIG. 1 is a schematic block diagram of a manufacturing device of mask assembly according to one embodiment of the present disclosure.

FIG. 2 is a schematic structural diagram of a manufacturing device of mask assembly according to one embodiment of the present disclosure.

FIG. 3 is a schematic view showing the forces applied to the mask when the mask is stretched by the manufacturing device according to one embodiment of the present disclosure.

FIG. 4A is a schematic structural view of a first stretching mechanism and/or a second stretching mechanism in one embodiment of the present disclosure.

FIG. 4B is a schematic view of the mask being clamped by the first stretching mechanism and/or the second stretching mechanism in one embodiment of the present disclosure.

FIG. 4C is a schematic structural top view of the first stretching mechanism in one embodiment of the present disclosure.

FIG. 5 is a schematic flow chart of a method of manufacturing the mask assembly according to one embodiment of the present disclosure.

FIG. 6A is a schematic view of a mask frame with a grid holder formed thereon in one embodiment of the present disclosure.

FIG. 6B is a schematic view of a mask assembly provided with a mask in one embodiment of the present disclosure.

FIG. 6C is an enlarged schematic view of the encircled area in FIG. 6B.

FIG. 6D is a schematic view of a mask assembly after the cutting treatment of the mask edges in one embodiment of the present disclosure.

FIG. 6E is a schematic view of a mask assembly provided with second shielding strips in one embodiment of the present disclosure.

FIG. 6F is a schematic view of a mask after a pre-deformation treatment in one embodiment of the present disclosure.

FIG. 7 is a schematic view showing a mask of a mask assembly manufactured by the manufacturing method according to one embodiment of the present disclosure, compared with a mask of a mask assembly not manufactured by the manufacturing method of the present disclosure.

### DETAILED DESCRIPTION OF THE EMBODIMENTS

In order to make the object, technical solutions and advantages of the present disclosure clearer, the present disclosure will be described in further detail below in association with specific embodiments and with reference to the accompanying drawings.

It should be noted that, all expressions using “first” and “second” in the embodiments of the present disclosure are intended to distinguish between two different entities or parameters with the same name. Thus “first” and “second” are only used for the clarity of expression and should not be construed as limiting the embodiments of the present disclosure. This also applies to other embodiments.

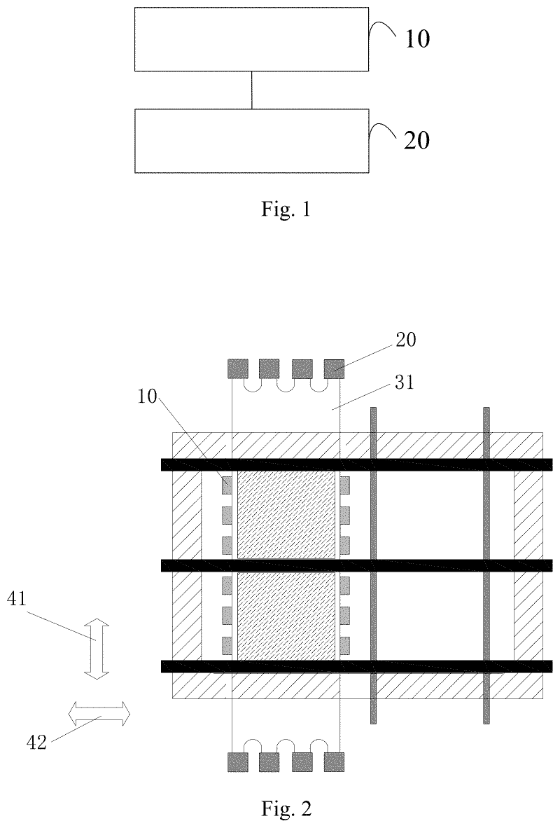

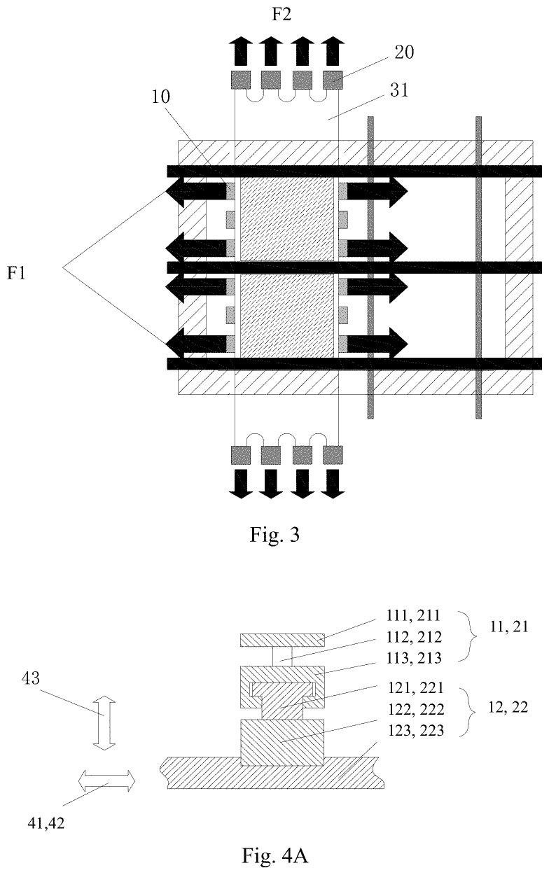

FIGS. 1 and 2 respectively show a schematic block diagram and a schematic structural view of a manufacturing device of mask assembly according to one embodiment of the present disclosure. FIG. 3 is a schematic view showing the forces applied to the mask when the mask is stretched by the manufacturing device of mask assembly according to one embodiment of the present disclosure. As shown in these figures, the manufacturing device of mask assembly may comprise a first stretching mechanism 10 and a second stretching mechanism 20, the mask assembly may comprise at least one mask 31, wherein the first stretching mechanism 10 is configured to clamp the edges of the mask 31 in the first direction 41 and stretch the mask 31 in the second direction 42 (the arrows in FIG. 3 show the application direction of the stretching force F1), and the second stretching mechanism 20 is configured to clamp the edges of the mask 31 in the second direction 42 and stretch the mask 31 in the first direction 41 (the arrows in FIG. 3 show the application direction of the stretching force F2), and wherein the first direction 41 is perpendicular to the second direction 42.

Optionally, the manufacturing device may further comprise a main body, wherein the first stretching mechanism 10 and the second stretching mechanism 20 are both disposed on the main body, so that the main body can provide a support for the first stretching mechanism 10 and the second stretching mechanism 20. For example, the main body can also provide a source of stretching force for the first stretching mechanism 10 and the second stretching mechanism 20, such as a motor, a screw rod, a hydraulic cylinder, and the like.

As can be seen from the above-mentioned embodiments, the manufacturing device according to the present disclosure can, by stretching the mask in two directions, effectively reduce mask wrinkles, make the magnetic force bond between the magnetic plate of the evaporation device and the mask more tightly, reduce the gap between the substrate to be vapor-deposited and the mask, and reduce shadowing effect, improper color mixing and etc.

Preferably, when the manufacturing device is used for manufacturing large-size AMOLED panels, mask wrinkles can be effectively reduced, and the quality of the evaporation process can be improved. Meanwhile, the embodiments of the present disclosure enable less waste of the mask materials, and also meet the manufacturing precision requirement for large-size masks.

Alternatively, as shown in FIG. 2, the manufacturing device may have a plurality of (e.g. 6) first stretching mechanisms 10, and the plurality of first stretching mechanisms 10 are arranged at equal intervals along the first direction 41. Also, the manufacturing device may have a plurality of (e.g. 4) second stretching mechanisms 20, and the plurality of second stretching mechanisms 20 are arranged at equal intervals along the second direction 42. In this way, by performing stretching at a plurality of positions, wrinkles of the entire mask formed in the first direction 41 and in the second direction 42 can be effectively reduced. The numbers depicted in the figures are merely exemplary, and other suitable numbers depending on the size of the mask are also within the scope of the present application.

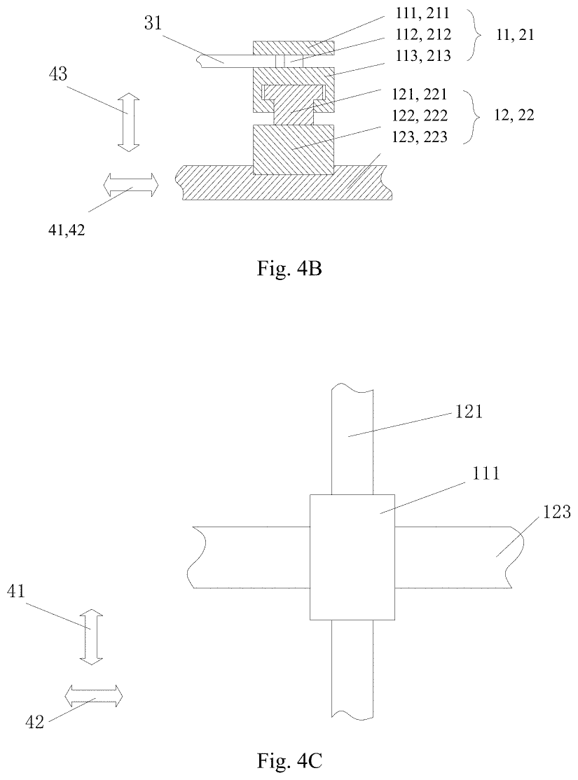

According to an alternative embodiment, as shown in FIGS. 4A to 4C, at least one of the first stretching mechanism 10 and the second stretching mechanism 20 may comprise clamping units 11, 21 and sliding units 12, 22, wherein the clamping units are configured to clamp the edges of the mask 31 in the first direction 41, and the sliding units are configured to drive the clamping units 11, 21 to move along the second direction 42; or the clamping units are configured to clamp the edges of the mask 31 in the second direction 42, and the sliding units are configured to drive the clamping units 11, 21 to move along the first direction 41, thereby causing the clamping units 11, 21 to stretch the mask 31 along the second direction 42 or the first direction 41.

Optionally, the first stretching mechanism 10 and the second stretching mechanism 20 may each comprise a clamping unit and a sliding unit, wherein the first stretching mechanism 10 may comprise a clamping unit 11 and a sliding unit 12, and the second stretching mechanism 20 may comprise a clamping unit 21 and a sliding unit 22.

According to an alternative embodiment, as shown in FIGS. 4A to 4C, the clamping units 11 and 21 may comprise movable clamping jaws 111 and 211, clamping jaw lifting parts 112 and 212, and clamping jaw bases 113 and 213. The movable clamping jaws 111, 211 can move relative to the clamping jaw bases 113, 213 along a third direction 43 through the driving of the clamping jaw lifting parts 112, 212, and the third direction 43 is perpendicular to both the first direction 41 and the second direction 42. There is a space formed between the movable clamping jaws 111, 211 and the clamping jaw bases 113, 213 to receive and clamp the edges of the mask 31 in the first direction 41 or the second direction 42. In this way, by controlling the size of the space formed between the movable clamping jaws 111, 211 and the clamping jaw bases 113, 213 through the expansion and contraction of the clamping jaw lifting parts 112, 212, the clamping of edges of the mask 31 in the first direction 41 or the second direction 42 is realized, which is simple and convenient. In the present application, the first direction can be understood as the X direction, the second direction is the Y direction and the third direction is the Z direction in the spatial rectangular coordinate system.

According to an alternative embodiment, as shown in FIGS. 4A to 4C, the sliding units 12, 22 may comprise first sliding rails 121, 221, bases 122, 222, and second sliding rails 123, 223. The first sliding rails 121, 221 extend along the first direction 41 or the second direction 42, the second sliding rails 123, 223 extend along the second direction 42 or the first direction 41, and the extending directions of the first sliding rails 121, 221 and the second sliding rails 123, 223 are perpendicular to each other. The first sliding rails 121, 221 are fixed to the bases 122, 222, and the clamping units 11, 21 are disposed on the first sliding rails 121, 221. The bases 122, 222 are arranged on the second sliding rails 123, 223 and can slide along the second sliding rails 123, 223.

A schematic structural top view of the first stretching mechanism is shown in FIG. 4C. Assuming that the edges of the mask 31 in the first direction 41 are clamped by the movable clamping jaw 111 and the clamping jaw base 113 (as shown in FIG. 4B) and stretched along the second direction 42, then the base 122 (as shown FIG. 4B) may move along the second sliding rail 123 in the second direction 42, and at this time, the mask 31 may slightly deform in the first direction 41 due to the stretching of the mask 31. In this case, the clamping jaw base 113 may also move along the first sliding rail 121 (i.e. the first direction 41) with the slight deformation of the mask 31, so as not to wrinkle the mask.

In the case where the second stretching mechanism has the same configuration as the first stretching mechanism, the working principle for stretching is basically the same as that of the first stretching mechanism and will not be repeated here.

Optionally, the friction coefficient between the first sliding rails 121, 221 and the clamping units 11, 21 (e.g. the clamping jaw bases 113, 213) is different from that between the second sliding rails 123, 223 and the bases 122, 222, wherein the sliding rails with higher friction coefficient are used to perform stretching, and the sliding rails with lower friction coefficient are used to enable the clamping jaws to move freely in the other direction along with the deformation of the mask, that is, to provide a freedom of movement in the other direction. Thus, the selection of the specific friction coefficient depends on the required functions for the sliding rails and thus is not defined here. For example, if the first sliding rails are used to enable the clamping jaws to move freely in the other direction along with the deformation of the mask, the friction coefficient between the first sliding rails and the clamping units is lower, and the second sliding rails are used to perform stretching, the friction coefficient between the second sliding rails and the bases is higher.

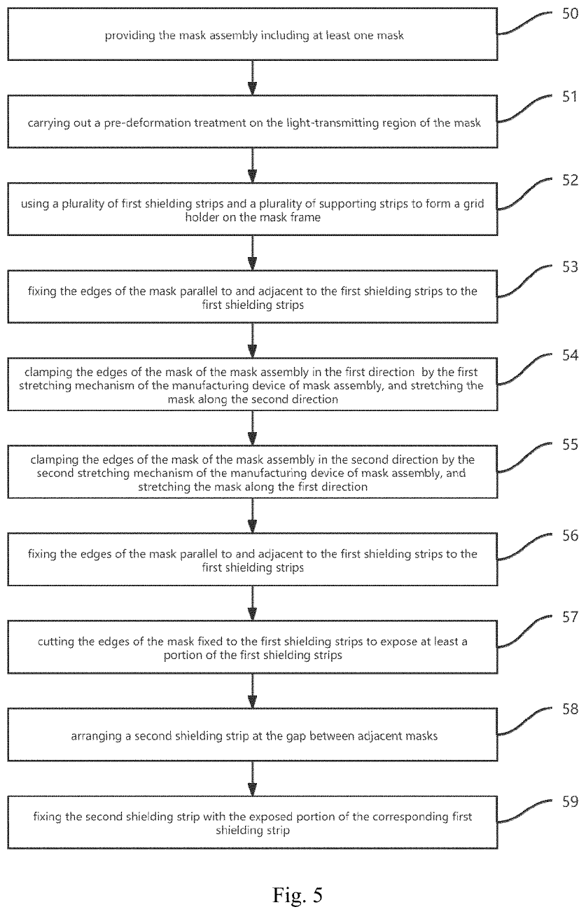

FIG. 5 shows a schematic flow chart of a method of manufacturing a mask assembly according to one embodiment of the present disclosure.

As shown in FIG. 5 and referring to FIG. 3, the manufacturing method may comprise:
Step 50: providing the mask assembly including at least one mask;
step 54: clamping the edges of the mask 31 of the mask assembly in the first direction 41 by the first stretching mechanism 10 of the manufacturing device of mask assembly, and stretching the mask along the second direction 42;
step 55: clamping the edges of the mask 31 of the mask assembly in the second direction 42 by the second stretching mechanism 20 of the manufacturing device of mask assembly, and stretching the mask 31 along the first direction 41;

wherein the first direction 41 is perpendicular to the second direction 42.

As can be seen from the above-mentioned embodiments, the manufacturing method according to the present disclosure can, by stretching the mask in two directions, effectively reduce mask wrinkles, make the magnetic force bonding between the magnetic plate of the evaporation device and the mask more tightly, reduce the gap between the substrate to be vapor-deposited and the mask, and reduce shadowing effect, improper color mixing and etc.

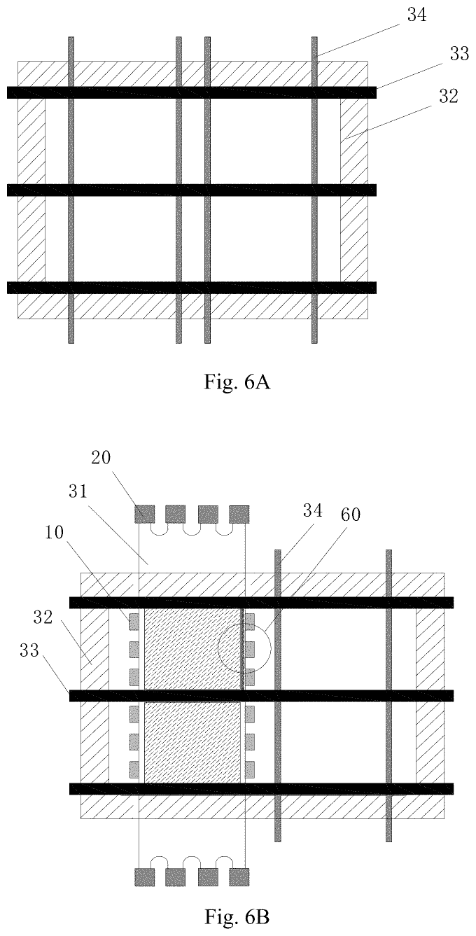

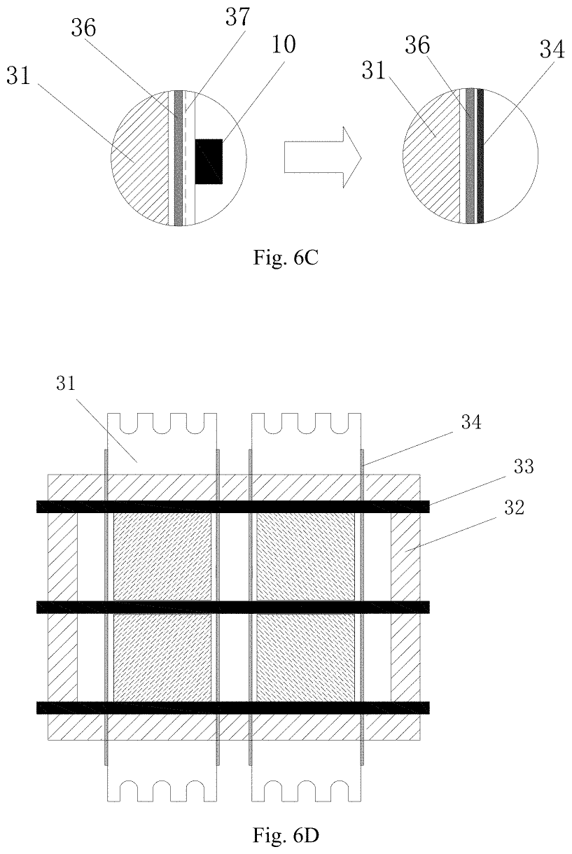

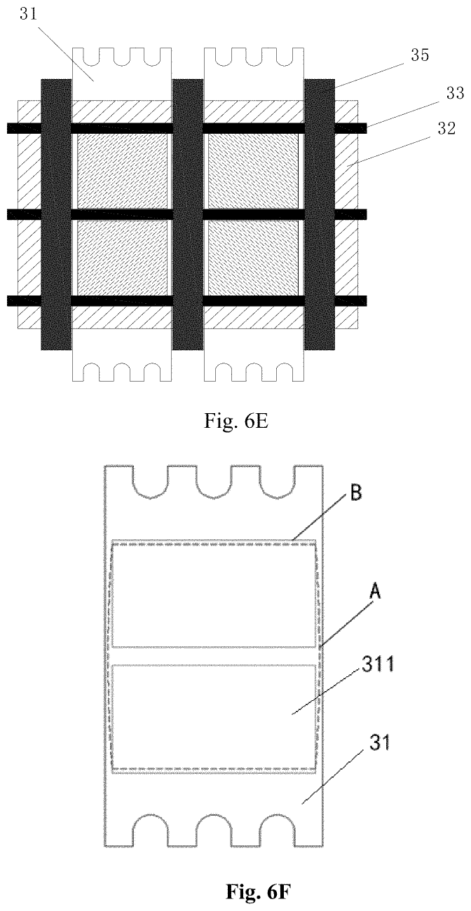

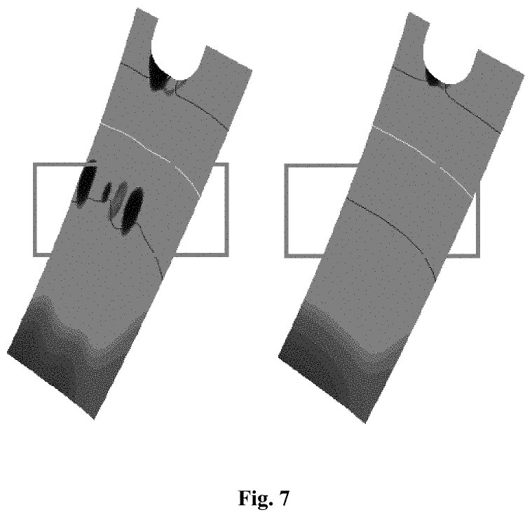

In one embodiment, as shown in FIG. 5, the manufacturing method further comprises:
step 52: using a plurality of first shielding strips 34 and a plurality of supporting strips 33 to form a grid holder on the mask frame 32. Although there are four shielding strips 34 and three supporting strips 33 shown in FIG. 6A, this is merely exemplary and does not limit the disclosure, and other suitable numbers of shielding strips and supporting strips also fall within the protection scope of the present application;
step 53: sandwiching the mask 31 between two adjacent first shielding strips 34, as shown in FIG. 6B;

wherein the plurality of first shielding strips 34 are arranged in parallel along the first direction 41, the plurality of supporting strips 33 are arranged in parallel along the second direction 42; or the plurality of first shielding strips 34 are arranged in parallel along the second direction 42, the plurality of supporting strips 33 are arranged in parallel along the first direction 41, and the extending direction of the first shielding strips 34 is perpendicular to the extending direction of the supporting strips 33.

Optionally, gaps may be left between two adjacent first shielding strips 34 and between each of the first shielding strips 34 and the mask frame 32, such that the clamping units can move. Alternatively, the crossing points of the first shielding strips 34 and the supporting strips 33 may be fixed by welding, for example, in order to restrict the movement of the shielding strips 34 along the second direction 42 after the stretching operation. Of course, other suitable fixing means are also feasible and covered by the scope of this application.

In one embodiment, as shown in FIG. 5, the mask assembly manufacturing method may further comprise:
step 56: fixing the edges of the mask 31 parallel to and adjacent to the first shielding strips 34 to the first shielding strips 34, after the mask 31 is stretched and tensioned in the first direction 41 and the second direction 42. Alternatively, the edges of the mask 31 parallel to and adjacent to the first shielding strips 34 may be fixed to the first shielding strips 34 by welding.

In this way, by fixing the mask 31 to the first shielding strips 34, the mask 31 is prevented from wrinkling and sagging further due to the retraction of the mask 31 along the second direction 42.

In one embodiment, as shown in FIG. 5, the mask assembly manufacturing method may further comprise:
step 57: cutting the edges of the mask 31 fixed to the first shielding strips 34 to expose at least a portion of the first shielding strips 34; for example, FIG. 6C shows an enlarged schematic view of the encircled area 60 in FIG. 6B, wherein other portions of the mask 31 than the fixed portion 36 with the first shielding strips 34 are the portions to be cut, and after cutting along the cutting line 37, a portion of the first shielding strips 34 covered by the edges of the mask 31 is exposed (shown on the right side in FIG. 6C); the mask assembly after cutting is shown in FIG. 6D;
step 58: arranging a second shielding strip 35 at the gap between adjacent masks 31;
step 59: fixing the second shielding strip 35 with the exposed portion of the corresponding first shielding strip 34, as shown in FIG. 6E.

In this way, a final mask assembly is formed by providing a second shielding strip 35 at the gap between adjacent masks 31. In addition, since the edges of the mask 31 have undergone cutting operation, the second shielding strip 35 disposed at the gap between adjacent masks 31 can be flush with the mask 31, and thus the entire mask assembly is flat. If the edges of the mask 31 have not been cut, the second shielding strip 35 will directly cover the edges of the mask 31, that is, the second shielding strip 35 will be above the mask 31, resulting in the subsequent untight fit of the mask, which may lead to color mixing problems.

In one embodiment, as shown in FIG. 5, the manufacturing method may further comprise:
step 51: carrying out a pre-deformation treatment on the light-transmitting region 311 of the mask 31.

As shown in FIG. 6F, the dashed line frame A is the boundary of the light-transmitting region 311 after being pre-deformed, and the solid line frame B is the boundary of the light-transmitting region 311 after being stretched and tensioned. Clearly, the tension of the light-transmitting region 311 counteracts the pre-deformation thereof.

The tensioned mask may still retract to a certain extent, which may lead to a pixel hole position deviation. In order to avoid this problem, the light-transmitting region of the mask is pre-deformed in the design of the mask, so that the pre-deformation will counteract the retraction deformation when the mask retracting and compensate for the pixel hole position deviation.

Alternatively, in the design of the mask, the compensation amount of the light-transmitting region of the mask can be obtained by virtue of the finite element simulation of the three-dimensional mechanical structure.

FIG. 7 is a schematic image showing a mask of a mask assembly manufactured by the method of manufacturing mask assembly according to one embodiment of the present disclosure, compared with a mask of a mask assembly not manufactured by the mask assembly manufacturing method according to one embodiment of the present disclosure, wherein the left side image is a simulation image of a mask of a mask assembly not manufactured by the mask assembly manufacturing method according to one embodiment of the present disclosure, and the right side image is a simulation image of a mask of a mask assembly manufactured by the mask assembly manufacturing method according to one embodiment of the present disclosure. It can be seen that the mask in the right-side image has been evenly stressed and no wrinkles appear on it.

In another aspect of one embodiment of the present disclosure, there is also provided a mask assembly manufactured by any embodiment of the method of manufacturing mask assembly or the combination of embodiments.

The mask assembly according to one embodiment of the present disclosure can, by stretching the mask in two directions during manufacturing, effectively reduce mask wrinkles, make the magnetic force bond between the magnetic plate of the evaporation device and the mask more tightly, reduce the gap between the substrate to be vapor-deposited and the mask, and reduce shadowing effect, improper color mixing and etc.

Preferably, when the mask assembly is used for manufacturing large-size AMOLED panels, the mask wrinkles can be effectively reduced, and the quality of the evaporation process is improved. For example, the mask 31 in the mask assembly is a fine metal mask (FMM).

In one embodiment, as shown in FIGS. 6A and 6B, the mask assembly may comprise a mask frame 32, first shielding strips 34, supporting strips 33 and at least one mask 31. These first shielding strips 34 and supporting strips 33 form a grid holder, which is disposed on the mask frame 32. The mask 31 may be sandwiched between two adjacent first shielding strips 34. The first shielding strips 34 are arranged in parallel along the first direction 41, the supporting strips 33 are arranged in parallel along the second direction 42; or the first shielding strips 34 are arranged in parallel along the second direction 42, the supporting strips 33 are arranged in parallel along the first direction 41, and the extending direction of the first shielding strips 34 is perpendicular to the extending direction of the supporting strips 33.

In one embodiment, as shown in FIG. 6B, the edges of the mask 31 parallel to and adjacent to the first shielding strips 34 are fixed to the first shielding strips 34, after the mask 31 is stretched and tensioned in the first direction 41 and the second direction 42.

In this way, by fixing the mask 31 to the first shielding strips 34, the mask 31 is prevented from wrinkling and sagging further due to the retraction of the mask 31 along the second direction 42.

In one embodiment, as shown in FIGS. 6C-6E, the mask assembly may further comprise second shielding strips 35. The edges of the mask 31 fixed to the first shielding strips 34 are cut to expose at least a portion of the first shielding strips 34. The second shielding strips 35 are each disposed at a gap between adjacent masks 31, and each of the second shielding strips 35 is fixed to the exposed portion of the corresponding first shielding strip 34.

In this way, a final mask assembly is formed by providing a second shielding strip 35 at the gap between adjacent masks 31.

In one embodiment, as shown in FIG. 6F, the mask 31 of the mask assembly may have a pre-deformed light-transmitting region 311.

The tensioned mask may retract to a certain extent, which may lead to pixel hole position deviation. In order to avoid this problem, the light-transmitting region of the mask is pre-deformed in the design of the mask, so that the pre-deformation will just counteract the retraction deformation when the mask retracts, and compensate for the pixel hole position deviation.

Those of ordinary skill in the art will understand that, the discussion of any of the above embodiments is merely exemplary and is not intended to imply that the scope of the present disclosure (including the claims) is limited to these examples. Based on the idea of this application, the technical features of the above embodiments or different embodiments can also be combined, the steps can be implemented in any order, and there may be many other changes in different aspects of this application as described above, which are not specified in detail for the sake of brevity.

The embodiments of the present disclosure are intended to cover all such alternatives, modifications and variations that fall within the broad scope of the appended claims. Therefore, any omission, modification, equivalent substitution, improvement, etc. made within the spirit and principles of this disclosure shall be included within the protection scope of this disclosure.

1. A manufacturing device of mask assembly including at least one mask, comprising:
a first stretching mechanism configured to clamp the edges of the mask in a first direction and stretch the mask in a second direction; and
a second stretching mechanism configured to clamp the edges of the mask in the second direction and stretch the mask in the first direction;
wherein the first direction being perpendicular to the second direction.

2. The manufacturing device according to claim 1, wherein at least one of the first stretching mechanism and the second stretching mechanism comprises:
a clamping unit configured to clamp the edges of the mask in the first direction or the second direction; and
a sliding unit configured to drive the clamping unit to move along the second direction or the first direction, thereby causing the clamping unit to stretch the mask along the second direction or the first direction.

3. The manufacturing device according to claim 2, wherein the clamping unit comprises a movable clamping jaw, a clamping jaw lifting part and a clamping jaw base, wherein the movable clamping jaw can move along a third direction relative to the clamping jaw base under the driving of the clamping jaw lifting part, the third direction being perpendicular to both the first direction and the second direction, and wherein there is a space formed between the movable clamping jaw and the clamping jaw base to receive and clamp the edges of the mask in the first direction or the second direction.

4. The manufacturing device according to claim 2, wherein the sliding unit comprises:
a base;
a first sliding rail fixed to the base and extending along the first direction or the second direction;
a second sliding rail extending along the second direction or the first direction;
wherein the extending direction of the first sliding rail and that of the second sliding rail are perpendicular to each other, and the clamping unit is arranged on the first sliding rail, and wherein the base is arranged on the second sliding rail and can slide along the second sliding rail.

5. The manufacturing device according to claim 4, wherein the friction coefficient between the first sliding rail and the clamping unit is different from that between the second sliding rail and the base.

6. The manufacturing device according to claim 1, wherein the manufacturing device comprising a plurality of first stretching mechanisms and a plurality of second stretching mechanisms, wherein the plurality of first stretching mechanisms are arranged at equal intervals along the first direction, and the plurality of second stretching mechanisms are arranged at equal intervals along the second direction.

7. A method of manufacturing a mask assembly, comprising the steps of:
providing the mask assembly including at least one mask;
clamping the edges of the mask of the mask assembly in a first direction by a first stretching mechanism of a manufacturing device of mask assembly, and stretching the mask along a second direction;
clamping the edges of the mask of the mask assembly in the second direction by a second stretching mechanism of the manufacturing device of mask assembly, and stretching the mask along the first direction;
wherein the first direction is perpendicular to the second direction.

8. The method according to claim 7, further comprising:
using a plurality of first shielding strips and a plurality of supporting strips to form a grid holder on a mask frame;
sandwiching the mask between two adjacent first shielding strips;
wherein the plurality of first shielding strips are arranged in parallel along the first direction, and the plurality of supporting strips are arranged in parallel along a second direction; or the plurality of first shielding strips are arranged in parallel along the second direction, and the plurality of supporting strips are arranged in parallel along the first direction, and the extending direction of the first shielding strips are perpendicular to the extending direction of the supporting strips.

9. The method according to claim 8, further comprising:
fixing the edges of the mask parallel to and adjacent to the first shielding strips to the first shielding strips after the mask is stretched and tensioned along the first direction and the second direction.

10. The method according to claim 9, further comprising:
cutting the edges of the mask fixed to the first shielding strips to expose at least a portion of the first shielding strips;
arranging a second shielding strip at a gap between adjacent masks;
fixing the second shielding strip to the exposed portion of the corresponding first shielding strip.

11. The method according to claim 7, further comprising:
carrying out a pre-deformation treatment on a light-transmitting region of the mask.

12. A mask assembly manufactured by the method of manufacturing a mask assembly according to claim 7.

13. The mask assembly according to claim 12, wherein the mask assembly comprises a mask frame, a plurality of first shielding strips, a plurality of supporting strips and at least one mask,
wherein the first shielding strips and the supporting strips form a grid holder, and the grid holder is disposed on the mask frame, and the mask is sandwiched between two adjacent first shielding strips,
wherein the plurality of first shielding strips are arranged in parallel along a first direction, and the plurality of supporting strips are arranged in parallel along a second direction; or the plurality of first shielding strips are arranged in parallel along the second direction, and the plurality of supporting strips are arranged in parallel along the first direction, and the extending direction of the first shielding strips are perpendicular to the extending direction of the supporting strips.

14. The mask assembly according to claim 13, wherein the edges of the mask parallel to and adjacent to the first shielding strips are fixed to the first shielding strips after the mask is stretched and tensioned along the first direction and the second direction.

15. The mask assembly according to claim 14, wherein the mask assembly further comprises a second shielding strip, wherein the edges of the mask fixed to the first shielding strips are cut to expose at least a portion of the first shielding strips, the second shielding strip is disposed at a gap between adjacent masks, and fixed to the exposed portion of the corresponding first shielding strip.

16. The mask assembly according to claim 12, wherein the mask of the mask assembly has a pre-deformed light-transmitting region.
